(19) United States
(12) Patent Application Publication
(10) Pub. No.: US 2008/0150626 A1
(43) Pub. Date: Jun. 26, 2008

(54) Time variant filter with reduced settling time

(75) Inventor: William C. DeAgro, Shirley, NY (US)

Correspondence Address: PIETRAGALLO GORDON ALFANO BOSICK & RASPANTI, LLP, ONE OXFORD CENTRE, 38TH FLOOR, 301 GRANT STREET, PITTSBURGH, PA, 15219-6404, US

(73) Assignee: Northrop Grumman Systems Corporation, Los Angeles, CA (US)

(21) Appl. No.: 11/643,291

(22) Filed: Dec. 21, 2006

(51) Int. Cl. H03H 11/12; H03H 11/04

(52) U.S. Cl. 327/553

(57) ABSTRACT

A system includes an input for receiving an input signal, a filter having a changeable time constant, and a control circuit for changing the filter time constant in response to a property of the input signal.

### FIELD OF THE INVENTION

This invention relates to electronic circuits and more particularly to electronic filters and methods of operating electronic filters.

### BACKGROUND OF THE INVENTION

There is an increasing need for electronic systems that operate faster, process more data, and include more features and capability than previous generation equipment.

Signal processing systems can frequently receive inputs from several sources. Most signal processing and signal conditioning circuitry and software includes some type of conditioning filtering. When a measurement process is interrupted to process a different signal (for example, the switching in and out of built in test (BIT), built in test and evaluation (BITE), or calibration signals, and/or switching among different input signals for measurement or synthesis), there is generally a filter settling time penalty. For example, consider an electronic countermeasures (ECM) jamming system working against transient type signals, perhaps including frequency hopping. The system must process and filter incoming signals before the target emitter changes so that the target emitter can be jammed properly. Filtering takes large chunks of time to complete and is, or will become, a bottleneck in many processes.

Since the minimum duration for settling in ordinary fixed filters is limited or bounded, and surrounding hardware will continue to become faster due to technological advances and demands, filter settling time will become more critical to system capability and performance. If measured inputs or synthesized outputs are to be constantly changed prior to filtering in an application, settling time becomes critical.

Previous and other methods for speeding up the filtering process are not optimum and result in performance degradations in terms of noise, quantization error, aliasing and inconsistency, for both in band and out of band signals.

To meet the needs of future technological demand, new techniques for the reduction of filter settling time need to be devised and employed. This invention seeks to reduce filter settling time, while maintaining other performance parameters such as the rejection of noise and the rejection of out of band undesired signal components.

### SUMMARY OF THE INVENTION

In a first aspect, the invention provides an apparatus including an input for receiving an input signal, a filter having a changeable time constant, and a control circuit for changing the time constant in response to a property of the input signal.

In another aspect, the invention provides an apparatus including a filter for receiving an input signal and having a changeable time constant, and a control circuit for increasing the time constant during a time period following initial receipt of the input signal.

In another aspect, the invention provides an apparatus including a multiplexer having a plurality of inputs for receiving a plurality of input signals, a filter for receiving one of the input signals from the multiplexer and having a changeable time constant, and a control circuit for changing the time constant in response to changes in the input signals.

The invention also encompasses a method of reducing the settling time of an electronic system. The method includes the steps of providing a filter having a changeable time constant, connecting an input signal to the electronic system; using the filter to filter an input signal to produce a filtered signal, and changing the time constant in response to a property of the input signal to reduce a settling time of the filtered signal.

The invention further encompasses a method including the steps of providing a filter for receiving an input signal and having a changeable time constant; and increasing the time constant during a time period following initial receipt of the input signal.

The invention also encompasses a method including the steps of providing a filter having a changeable time constant, alternatively connecting one of a plurality of input signals to the filter, using the filter to filter the input signal to produce a filtered signal, and changing the time constant in response to a change in the input signal to reduce a settling time of the filtered signal.

### BRIEF DESCRIPTION OF THE DRAWINGS

FIG. 1 is a block diagram of an electronic system that can be constructed in accordance with the invention.

FIG. 2 is a graph that illustrates rise time and settling time for a fixed resistor capacitor (RC) filter example.

FIG. 3 is a schematic diagram of a system including a time variant filter constructed in accordance with the invention.

FIG. 4 is a graph that illustrates the final portion of the rise time and settling time for a time variant filter.

FIGS. 5 and 6 are schematic diagrams of other time variant filters having multiple staging for improved rolloff and performance, which can be constructed in accordance with the invention.

FIG. 7 is a schematic diagram of a bandpass filter also using multiple staging.

FIG. 8 is a schematic diagram of a system containing a digital filter constructed in accordance with the invention.

### DETAILED DESCRIPTION OF THE INVENTION

Most commonly, systems, measurement, and stimulus apparatus and equipment convert signals to baseband and/or require anti-aliasing filters. In such cases a lowpass filter is employed. Some of the important parameters for such a filter include the bandwidth, settling time, and out of band rejection. In many designs, filter bandwidth (which is inversely proportional to settling time) is traded off and kept wide in order to keep the settling time at an acceptable level. In doing so, more poles (and hardware) are required to achieve out of band rejection goals for the filter. Furthermore, the downfall is that the rejection of noise is less with a wider bandwidth filter. This invention seeks to significantly speed up the filtering process without degradation to performance.

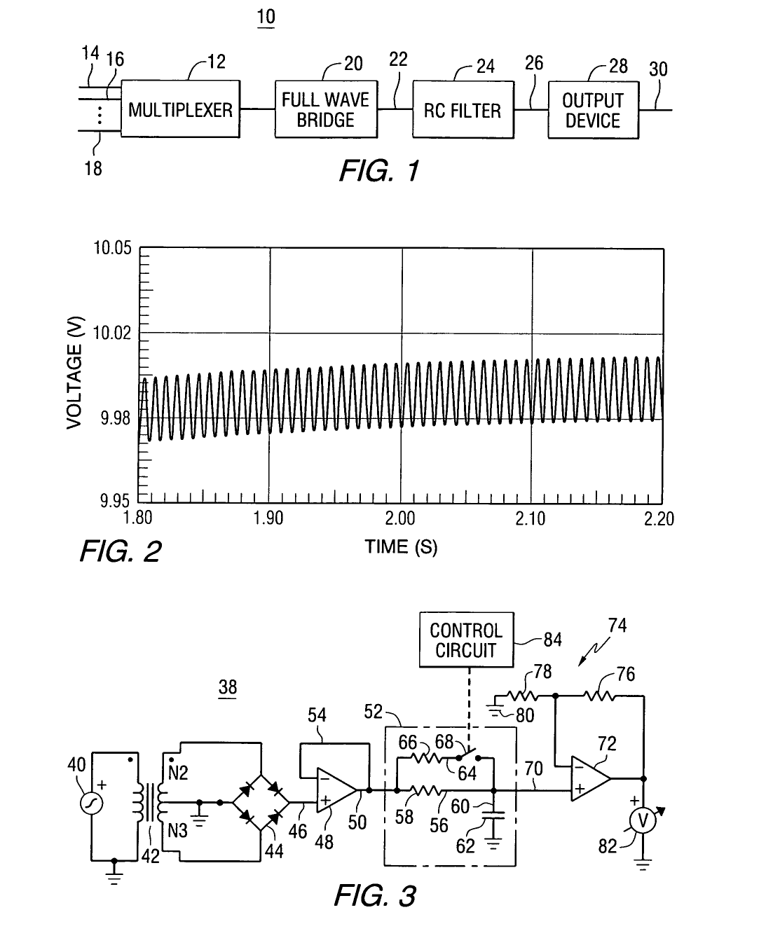

Referring to the drawings, FIG. 1 is a block diagram of an example electronic system 10 that can be constructed in accordance with the invention. The system includes a multiplexer 12 having a plurality of inputs 14, 16 and 18, which can receive signals from various sources. The multiplexer is used to select between these inputs and to pass the selected signal to a full wave bridge rectifier 20. A resulting rectified signal on line 22 is passed to a simple single pole analog RC filter 24. The filtered signal on line 26 is processed as illustrated in block 28 to produce an output on line 30.

In one example of the invention, a remote controlled device (such as for example a Versa Module Eurocard (VME) type card) is used to measure a number of signals within a system. Suppose one of the signals to be measured is 60 Hz power. The circuitry for the VME card can be relatively simple, for example including an input multiplexer (to select one of N inputs), a full wave bridge, a fixed single pole lowpass (RC) filter and a digital output as shown in the block diagram in FIG. 1.

Now assume that the gains/attenuations of the various components are set such that the output of the filter 24 will reach 10 Vdc when settled, and an accuracy of 0.02% is desired. To simplify this description, the output of the full wave bridge is assumed to have a low impedance for this example. If the RC filter is designed such that 0.01% of the error budget is due to ripple and 0.01% of the error budget is due to a predetermined time constraint, then about 2.2 seconds would be needed to settle the filter output signal to the desired level.

FIG. 2 shows the latter portion of the rise and settling time enlarged for a fixed RC filter example for the range of 1.8 to 2.2 seconds after the initial application of the signal (at t=0), for a lowpass RC filter having a series R=1 KΩ and a shunt C=270 μF. The rise time is a measure of the time required for the output to change from one level to another once a level change to the input has been started, and the settling time is the time required for the output to enter and remain within a specified narrow band centered on its steady-state value after a level change occurred, which in this example is 0.01% due to output ripple.

Using the time variant filter approach of this invention, the filter time constant can be altered automatically. FIG. 3 is a schematic diagram of a circuit 38 including a time variant filter constructed in accordance with an embodiment of the invention. In FIG. 3, a signal source 40 (or an embedded signal within a system, depending on the application) provides a signal to a transformer 42. The output of the transformer is rectified by full wave rectifier bridge 44 and the rectified signal on line 46 is provided to the positive input of operational amplifier 48. The output 50 of the operational amplifier serves as an input to filter 52, and is also fed back to the negative input of the operational amplifier as illustrated by line 54. The filter 52 is a time variant lowpass filter, which includes a first circuit branch 56 including a first resistor 58 and a second circuit branch 60 including a first capacitor 62. A third circuit branch 64 includes the series connection of a second resistor 66 and a switch 68, and is connected in parallel with resistor 58. The output 70 of the filter is connected to the positive input of a second operational amplifier 72. A feed back circuit 74, including a third resistor 76 connects the output 70 of operational amplifier 72 to the negative input of the operational amplifier 72. Resistor 78 couples the negative input of the operational amplifier 72 to ground 80. An output device, such as a DC voltmeter 82 is used to provide a display of the output voltage of the operational amplifier 72. A switch control circuit or device 84 is provided to control the operation of the switch 68. The control circuit is used to control the time constant of the filter by opening and closing the switch. The control circuit can change the switch operating time in response to either a change in the input signal, for example, when the multiplexer selects different input signals, or in response to a property of the input signal.

If a priori knowledge of the input signal is known, the timing of the switch closure can be controlled to achieve improved results. For example, assume that the circuit is used to measure a 60 Hz power signal, which has a waveform that is fairly close to sinusoidal. The resistance of the circuit branch containing the switch can be set to be as low as possible (i.e., 0 Ohms) and a switch control circuit can be configured to trigger off the first zero crossing of the input signal. Then if the switch is closed at the zero crossing of the input signal and opened about 2.5 msec thereafter, the filter could settle in as little as about 1/120+2.5 ms=10.8 ms. Under this scenario, the capacitor voltage would be forced to follow the full wave rectified signal from the bridge until the switch opens. Once the switch opens, the full wave rectified signal level and capacitor voltage are close to a value, which is the same as the final settled value.

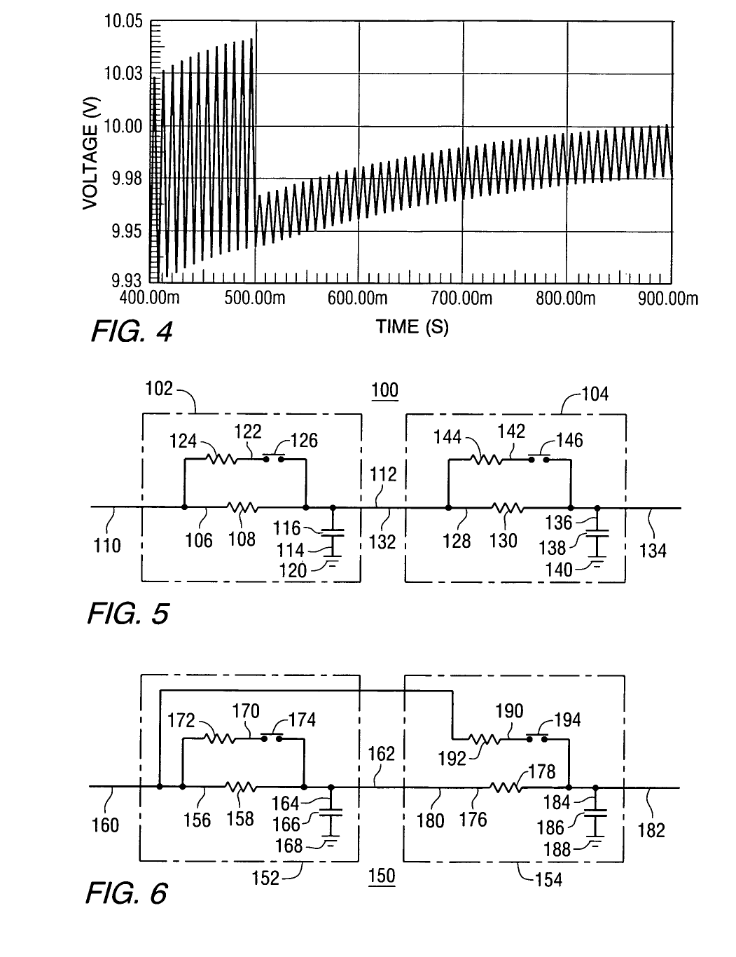

In another example where the input is a 60 Hz signal, switch 68 can be automatically controlled to open 0.5 seconds after the 60 Hz signal is connected to the circuit for measurement. FIG. 4 is a graph depicting an enlarged latter portion of the output rise time and final settling, for the range of 400 msec to 900 msec after application of the input voltage to the circuit using the time variant filter, assuming a 60 Hz input signal turned on at t=0, and the switch 68 opening at t=0.5 seconds. Settling has been reduced to 875 ms (which is better than a factor of 2.5).

In one embodiment, the switch can be an electronic switch having alternate conductive states, including a first state in which said electronic switch is non-conducting and a second state in which the electronic switch conducts fully, and a control input for controlling the conductive state of the electronic switch. Examples of some applicable switches are Vishay-Siliconix part numbers: DG201, DG211, DG303, DG411, DG442 and VN0300 single MOSFET.

There are many other instances in which certain characteristics of the signals to be filtered are known. For example, serializer/deserializer (S/D) and deserializer/serializer (D/S) circuits sometimes employ a phase detector circuit along with filtering in a phase-lock loop section where the above technique may be used for improvement.

Multipole, multizero, and combinations of filters may also be employed. FIGS. 5 and 6 are schematic diagrams of two pole time variant lowpass filters that can be constructed in accordance with the invention. FIG. 5 shows a filter 100, which includes two stages 102 and 104. The first stage comprises a first circuit branch 106 including a first resistor 108 connected between an input 110 and an output 112, and a second circuit branch 114 including a first capacitor 116 connected between the output 112 and ground 120. A third circuit branch 122 includes a third resistor 124 connected in series with the switch 126. The third circuit branch is connected in parallel with the first circuit branch. The second stage comprises a fourth circuit branch 128 including a fourth resistor 130 connected between an input 132 and an output 134, and a fifth circuit branch 136 including a second capacitor 138 connected between the output 134 and ground 140. A sixth circuit branch 142 includes a sixth resistor 144 connected in series with a switch 146. The sixth circuit branch is connected in parallel with the fourth circuit branch.

FIG. 6 shows a filter 150, which includes two stages 152 and 154. The first stage comprises a first circuit branch 156 including a first resistor 158 connected between an input 160 and an output 162, and a second circuit branch 164 including a first capacitor 166 connected between the output 162 and ground 168. A third circuit branch 170 includes a third resistor 172 connected in series with the switch 174. The third circuit branch is connected in parallel with the first circuit branch. The second stage comprises a fourth circuit branch 176 including a fourth resistor 178 connected between an input 180 and an output 182, and a fifth circuit branch 184 including a second capacitor 186 connected between the output 182 and ground 188. A sixth circuit branch 190 includes a sixth resistor 192 connected in series with the switch 194. The sixth circuit branch is connected in parallel with both the first and fourth circuit branches. The switches can be opened using a control signal from a remote location and resistance values can be changed and optimized according to specific design requirements.

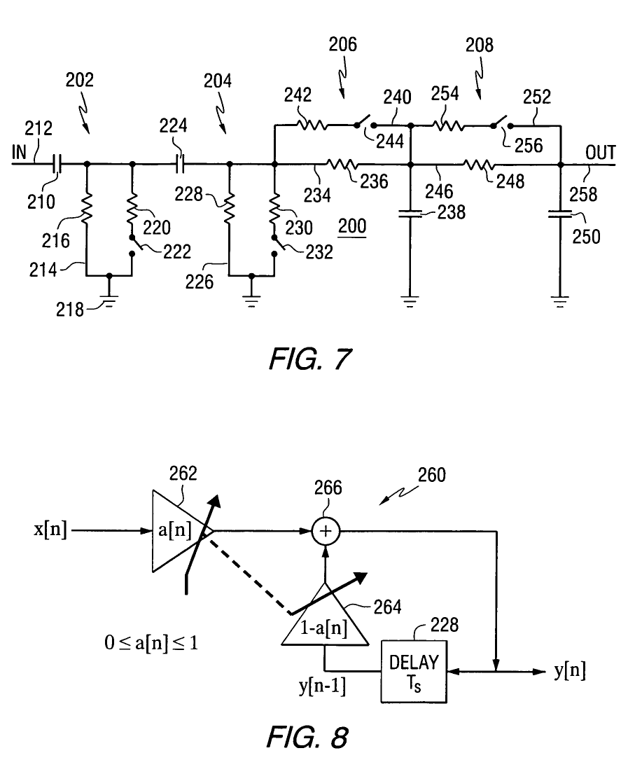

FIG. 7 is a schematic diagram of a bandpass filter 200 also using multiple staging. The filter includes two highpass multizero sections 202 and 204, and two lowpass multipole section 206 and 208. Section 202 includes a capacitor 210 connected to an input 212, a first circuit branch 214 including a resistor 216 connected between the capacitor and ground 218, and a second circuit branch including the series connection of a resistor 220 and a switch 222 connected between the capacitor and ground 218. Section 204 includes a capacitor 224 connected to section 204, a first circuit branch 226 including a resistor 228 connected between the capacitor and ground 218, and a second circuit branch including the series connection of a resistor 230 and a switch 232 connected between the capacitor and ground 218.

Section 206 includes a first circuit branch 234 including a resistor 236 connected between section 204 and a capacitor 238, and a second circuit branch 240 including the series connection of a resistor 242 and a switch 244 connected between section 204 and capacitor 238. The capacitor 238 is connected to ground 218. Section 208 includes a first circuit branch 246 including a resistor 248 connected between section 206 and a capacitor 250, and a second circuit branch 252 including the series connection of a resistor 254 and a switch 256 connected between section 206 and capacitor 250. The capacitor 250 is connected between an output 258 and ground 218. The switches can be operated to change the time constant of the filter.

Although digital signal processing is widely used, analog filters are still required for such things as anti-aliasing, image rejection, etc. However, the approach described above can also be directly extended to digital filters, with more flexibility and capability. In digital form, this is done by directly continuously varying the time constant.

FIG. 8 is a schematic block diagram of a digital lowpass type filter system 260 containing a variable digital filter constructed in accordance with the invention. The filter includes first and second variable amplifiers 262 and 264 having outputs connected to summation point 266. Amplifier 262 has a gain of a[n] and receives an input signal x[n]. The output of the summation point, y[n] is delayed 268 to produce a signal y[n−1] that is fed back to the input of amplifier 264. Amplifier 204 has a gain of 1−a[n].

For this example, a simple fixed analog lowpass Laplace filter transfer function H(S) takes the form of:

$$H ( S ) = \frac{α}{S + α} \qquad ( 1 )$$

where α is the reciprocal of the filter R·C time constant, and S is the Laplace Transform variable. From this, an equivalent digital simulator takes the form of:

$$H ( Z ) = \frac{a \cdot Z}{Z - 1 + a} \qquad ( 2 )$$

where a is normally a constant which sets the digital filter bandwidth and associated time constant. And Z is digital Z-Transform variable for the filter. For high digital sampling rates where α·Ts<<1 and Ts is the digital sampling interval, a=1−e^{-αTs}.

Expressing equation 2 as an infinite impulse response (IIR) filter in the time sampled domain results in:

y[n]=a·x[n]+(1−a)·y[n−1], (3)

where 0≦a≦1, and where y[n] is the digital output, x[n] is the digital input, n is the sample index, y[n−1] is the previous y value (from memory), and a is related to the analog filter R·C time constant per above.

When a=1, no filtering takes place and the bandwidth is infinite. With a value of a=1 the memory instantly becomes preloaded with the first incoming value, since the time constant for this digital filter is 0. At the other extreme when a=0, maximum filtering takes place and the bandwidth becomes 0 (as the time constant now becomes infinite), then everything is filtered out and nothing passes. The parameter a can easily be varied with time (from sample to sample) to adjust filter bandwidth and associated time constant with time. Varying parameter a also provides the ability to adjust filter bandwidth and associated time constant very frequently in many fine digital steps (instead of just one step as in the analog case with a single switch) and can be accomplished using either specific software coding or a digital hardware implementation to vary the parameter a with time.

Upon a remote control initiation, a may start out at (or close to) a value of 1. As samples come in (and time progresses), a will then be changed over and over in the direction towards 0 but will stop at a point of the final desired filter bandwidth (and for equivalence as that of the final bandwidth when switch 68 of FIG. 3 is open yielding a certain tolerable output ripple). The final desired bandwidth dictates how low a will become and the required settling time will be much quicker than all approaches discussed upon varying a. Forming a final filter equation with a as a variable under control and changing with time requires replacing a in the above equation by a[n] as shown in equation (4).

y[n]=a[n]·x[n]+(1−a[n])·y[n−1], (4)

where 0≦a[n]≦1.

In addition to the applications described above, there are applications where one may use such a filter and want to change the filter time constant, but not always in relation to the input signal or when a new signal is switched in by the multiplexer. As an example, the filter could be used in a remote type measurement apparatus, which may not have a multiplexer. The apparatus may have a single input and a controller may randomly request this apparatus to go out and take a measurement. If the apparatus utilizes a fixed filter, it may very likely be designed to wait for a period of time to allow for settling of the filter from the time the controller request was made, before actually responding with the measurement data. The rationale for this is that the controller may also be setting other things up in a system just prior to taking a measurement and it is likely that the input to the measurement apparatus had just become ready just prior to the controller making its request for a measurement and the filter in the measurement apparatus hasn't had time to settle yet. Using the time variant filter scheme proposed here, this wait time would reduce significantly by the measurement apparatus starting out (and possibly being in a normal state) with the filter set to a wide bandwidth (i.e., a short time constant). When the controller requests a measurement, the apparatus would automatically reduce the filter bandwidth (i.e., lengthen the time constant) with time and thereby converge to a settled result, and a final bandwidth that is equal to that of the fixed filter. Thus the filter would settle much faster and respond back to the controller much faster.

Normally one would design the filter with a time constant large enough to provide the necessary rejection. For example, the filter might be designed for <0.01% ripple. When using a controllable time constant filter, the controller could stop increasing the time constant once it became as long as that of the fixed filter design. In doing so, the filter output will settle to its final value much sooner than the fixed filter case. The rate at which the filter time constant is increased becomes a factor in how much improvement one obtains in settling time. Optimizing the rate is application dependent.

This technique can also be applied to more complex digital filters by varying coefficients with time for both infinite impulse response (IIR) and finite impulse response (FIR) filter types, as well as for lowpass, highpass, bandpass and cascaded bandpass filtering. As with any IIR filter, stability must be considered. The filter described by the above equations is stable (as long as a[n] is independently varied).

This invention can be implemented using all filter types (e.g., lowpass, highpass and bandpass). Circuits constructed in accordance with the invention filter signals with faster settling times while achieving better performance than other ordinary filter types in terms of noise rejection, sharper rolloff and out of band rejection. While the invention has been described in terms of several embodiments, it will be apparent to those skilled in the art that various changes can be made to the disclosed embodiments without departing from the scope of the invention as set forth in the following claims.

What is claimed is:

1. An apparatus comprising:
an input for receiving an input signal;
a filter having a changeable time constant; and
a control circuit for changing the time constant in response to a property of the input signal.

2. The apparatus of claim 1, wherein the filter comprises:
a switch for connecting or disconnecting a circuit branch in the filter, wherein the switch operates in response to a signal from the control circuit.

3. The apparatus of claim 1, wherein the filter comprises:
a first circuit branch connected between an input and an output;
a second circuit branch connected between the first circuit branch and a ground; and
a third circuit branch including a switch, wherein the third circuit branch is connected in parallel with at least a portion of the first circuit branch.

4. The apparatus of claim 3, wherein the first circuit branch comprises a first resistor, the second circuit branch comprises a capacitor, and the third circuit branch comprises a second resistor connected in series with the switch.

5. The apparatus of claim 1, wherein the filter comprises a multipole filter or a multizero filter.

6. The apparatus of claim 1, wherein the filter comprises a combination of pole and zero type filters.

7. The apparatus of claim 1, wherein the filter comprises a combination of multipole and multizero filters.

8. An apparatus comprising:
a filter for receiving an input signal and having a changeable time constant; and
a control circuit for increasing the time constant during a time period following initial receipt of the input signal.

9. An apparatus comprising:
a multiplexer having a plurality of inputs for receiving a plurality of input signals;
a filter for receiving one of the input signals from the multiplexer and having a changeable time constant; and
a control circuit for changing the time constant in response to changes in the input signals.

10. The apparatus of claim 9, wherein the filter comprises:
a switch for connecting or disconnecting a circuit branch in the filter, wherein the switch operates in response to a signal from the control circuit.

11. The apparatus of claim 9, wherein the filter comprises:
a first circuit branch connected between an input and an output;
a second circuit branch connected between the first circuit branch and a ground; and
a third circuit branch including a switch, wherein the third circuit branch is connected in parallel with at least a portion of the first circuit branch.

12. The apparatus of claim 11, wherein the first circuit branch comprises a first resistor, the second circuit branch comprises a capacitor, and the third circuit branch comprises a second resistor connected in series with the switch.

13. The apparatus of claim 9, wherein the filter comprises a multipole filter or a multizero filter.

14. The apparatus of claim 9, wherein the filter comprises a combination of pole and zero filters.

15. The apparatus of claim 9, wherein the filter comprises a combination of multipole and multizero filters.

16. A method of reducing settling time of an electronic system, the method comprising the steps of:
providing a filter having a changeable time constant;
connecting an input signal to the electronic system;
using the filter to filter the input signal to produce a filtered signal; and
changing the time constant in response to a property of the input signal to reduce a settling time of the filtered signal.

17. A method of reducing settling time of an electronic system, the method comprising the steps of:
providing a filter for receiving an input signal and having a changeable time constant; and
increasing the time constant during a time period following initial receipt of the input signal.

18. A method of reducing settling time of an electronic system, the method comprising the steps of:
providing a filter having a changeable time constant;
alternatively connecting one of a plurality of input signals;
using the filter to filter the input signal to produce a filtered signal; and
changing the time constant in response to a change in the input signal to reduce a settling time of the filtered signal.
